(19) United States
(12) Patent Application Publication
(10) Pub. No.: US 2025/0143060 A1
(43) Pub. Date: May 1, 2025

(54) LIGHT-EMITTING DEVICE AND DISPLAY APPARATUS

(71) Applicants: HGC (WUHAN) TECHNOLOGY CO., LTD, Wuhan (CN); HGC (ZHANGJIAGANG) SEMICONDUCTOR CO. LTD, Suzhou (CN)

(72) Inventors: Leimeng Sun, Wuhan (CN); Kun Li, Wuhan (CN); Fang Liu, Wuhan (CN)

(21) Appl. No.: 18/705,714

(22) PCT Filed: Dec. 31, 2021
(86) PCT No.: PCT/CN2021/143694

§ 371 Date: Apr. 29, 2024

(30) Foreign Application Priority Data
Dec. 6, 2021 (CN) 202111474793.7

(51) Int. Cl. H10H 29/85; H10H 29/80; H10H 29/851; H10H 29/855

(52) U.S. Cl. CPC H10H 29/857; H10H 29/8421; H10H 29/8514; H10H 29/8552

(57) ABSTRACT

A light-emitting device and a display apparatus. The light-emitting device extracts, by means of a light extraction member, light emitted from a side surface (a second light-emitting surface) of a semiconductor light source; the light from the side surface is collected to a top part to be emitted to a wavelength conversion member together with light from a first light-emitting surface; white light is emitted from a top part (a second abutting surface of the wavelength conversion member; and after passing through a light-transmitting layer, the white light is emitted from a top part of the light-transmitting layer that is in the thickness direction thereof and is provided with a light inhibition layer, and the white light from the top part is partially inhibited by the light inhibition layer.

### TECHNICAL FIELD

The present disclosure relates to the technical fields of light emitting semiconductors and backlight displays, and in particular to a light emitting device and a display device.

### BACKGROUND

With the development of small-pitch LED technology, more and more backlight modules use smaller-sized chips. Although a size of the chip is small and a light mixing distance is smaller than that of ordinary chips, it still requires 5 mm to 10 mm light mixing distance (optical distance, OD). Currently, the light emitted from the top of the chip is directly blocked to reduce the top luminescence. However, this solution will cause a luminous dark area on the top of the chip.

In view of this, it is desirable to provide a new light emitting device and display device to solve the above defect.

### SUMMARY

Accordingly, the present disclosure provides a light emitting device and a display device, which enhances the overall light intensity of the light emitting device through a light extraction member, while partially inhibiting the light emitted from a top surface of the light emitting device, weakening the light intensity at a top portion of the light emitting device, and providing an ultra-thin display device, and it will not cause dark areas or bright spots in the display device.

The present disclosure provides a light emitting device. The light emitting device includes a semiconductor light source including a first light emitting surface and an electrical connection surface opposite to each other, and a plurality of second light emitting surfaces connected between the first light emitting surface and the electrical connection surface, and two electrical connection members being provided on the electrical connection surface; a wavelength conversion member stacked on the first light emitting surface, the wavelength conversion member including a first abutting surface that abuts against the first light emitting surface, a second abutting surface that is opposite to the first abutting surface, and a side wall connected between the first abutting surface and the second abutting surface, the wavelength conversion member being configured to receive and convert a wavelength of light; a light extraction member surrounding the semiconductor light source and the wavelength conversion member, the light extraction member being spaced apart from the second light emitting surface and abuts against the side wall, the light extraction member being configured to extract light from the second light emitting surface; a light transmitting layer stacked on the second abutting surface, and a projection of the light transmitting layer along a stacking direction completely covering the second abutting surface; and a light inhibiting layer stacked on a top surface of the light transmitting layer away from the wavelength conversion member, and configured to partially inhibit a light emergent brightness of the top surface of the light transmitting layer, and an area of a projection of the light inhibiting layer on the second abutting surface along the stacking direction being less than an area of a projection of the light transmitting layer on the second abutting surface along the stacking direction.

Preferably, the light inhibiting layer is provided with a plurality of circular through holes, and the plurality of through holes are evenly distributed on the light inhibiting layer.

Preferably, projections of peripheral edges of the light inhibiting layer, the light transmitting layer and the second abutting surface coincide in the stacking direction.

Preferably, projections of peripheral edges of the light transmitting layer and the second abutting surface coincide in the stacking direction, and a projection of the peripheral edge of the light inhibiting layer in the stacking direction falls within the second abutting surface.

Preferably, the light transmitting layer is provided with a groove, and the groove is recessed from a surface of the light transmitting layer away from the wavelength conversion member toward the wavelength conversion member, the light inhibiting layer is accommodated in the groove, and the light inhibiting layer is coplanar with the light transmitting layer on a side away from the wavelength conversion member.

Preferably, the light emitting device further includes an expansion member connected to the two electrical connection members of the semiconductor light source. The expansion member includes two expansion sheets spaced apart and each having a front side and a back side opposite to each other, and an insulating reflective coating covering the two expansion sheets and having adhesiveness, the front surfaces of the two expansion sheets are connected to the two electrical connection members in one-to-one correspondence, respectively, the insulating reflective coating covers the expansion sheet in a manner of exposing the back side of the expansion sheet and partially exposing the front side of the expansion sheet, the insulating reflective coating further fills a gap between the two expansion sheets, and the front side of the expansion sheet and the insulating reflective coating located in the gap are further connected to the semiconductor light source.

Preferably, steps are provided on the back side of the expansion sheet, and the gap is formed between the steps of the two expansion sheets; and/or, the insulating reflective coating located on the front surface of the expansion sheet is distributed along a periphery away from the gap and is in a U-shape.

Preferably, a transparent sealing member is filled between the second light emitting surface and an inner wall of the light extraction member, the wavelength conversion member includes a first wavelength conversion film and a second wavelength conversion film sequentially stacked along a side adjacent to the semiconductor light source, the first wavelength conversion film excites light in the red wavelength band, the second wavelength conversion film excites light in the green wavelength band, and the transparent sealing member abuts against and seals the first wavelength conversion film.

Preferably, sealing member is filled between the second light emitting surface and an inner wall of the light extraction member, and a third wavelength conversion film that simultaneously excites light in the red wavelength band and light in the green wavelength band, reflective layers provided at both ends of the third wavelength conversion film along a direction perpendicular to the stacking direction, and a transparent layers provided at both sides of the third wavelength conversion film along the stacking direction, the transparent layers and the reflective layers wrap the third wavelength conversion film, and the transparent sealing member abuts against and seals the transparent layer.

The present disclosure further provides a display device. The display device includes a substrate, a plurality of light emitting devices arranged on the substrate, a reflective cover surrounding at least one of the light emitting devices, and a diffusion sheet stacked on the plurality of the light emitting devices, and a light-enhancing sheet. The light emitting device includes a structure of the light emitting device described above, a projection of the light emitting device in a direction parallel to the substrate falls within the reflective cover, the diffusion sheet abuts against the reflective cover, and the light-enhancing sheet is stacked on a side of the diffusion sheet away from the reflective cover.

The beneficial effect of the present disclosure is to provide a light emitting device and a display device. The light emitting device extracts the light emitted from the side surface (the second light emitting surface) of the semiconductor light source through the light extraction member, and the light from the side surface is collected to the top portion and then emitted to the wavelength conversion member together with the light emitted from the first light emitting surface, and the white light is emitted from the top portion (the second abutting surface) of the wavelength conversion member. After passing through the light transmission layer, the white light is emitted through the thickness direction of the light transmission layer and the top portion provided with the light inhibiting layer, and the white light at the top portion is partially inhibited by the light inhibiting layer. The light emitting device of the present disclosure can increase the overall light intensity and partially inhibit the light emitted from the top portion, thus avoiding the situation in the prior art that the top portion is directly completely inhibited, which results in a dark area on the top portion and an excessive loss of overall brightness. In addition, when used in display devices, the light mixing distance can be very small, the backlight device can be thinner and the overall brightness can be high.

### BRIEF DESCRIPTION OF THE DRAWINGS

FIG. 1 is a schematic view of a light emitting device according to a first embodiment of the present disclosure in a top view.

FIG. 2 is a cross-sectional view along the line M-M of FIG. 1.

FIG. 3 is an enlarged view of the portion A of FIG. 1.

FIG. 4 is a schematic view of the light emitting device according to a second embodiment of the present disclosure in a top view.

FIG. 5 is a cross-sectional view along the line N-N of FIG. 4.

FIG. 6 is a cross-sectional view of the light emitting device according to a third embodiment of the present disclosure along a stacking direction.

FIG. 7 is a cross-sectional view of the light emitting device according to a fourth embodiment of the present disclosure along a stacking direction;

FIG. 8 is a top view of an expansion member of FIG. 7.

FIG. 9 is a bottom view of an expansion member of FIG. 7.

FIG. 10 is a schematic view of an expansion sheet of the expansion member of FIG. 7 after a front side of an expansion sheet of the expansion member being shielded.

FIG. 11 is a schematic view of the front side of the expansion sheet of FIG. 10 being unshielded.

FIG. 12 is a schematic view of a back side of the expansion sheet of FIG. 10;

FIG. 13 is a cross-sectional view of a light emitting device according to a fifth embodiment of the present disclosure.

FIG. 14 is another cross-sectional view of a light extraction member according to the fifth embodiment.

FIG. 15 is an enlarged view of the portion B of FIG. 14.

FIG. 16 is a cross-sectional view of a display device according to a sixth embodiment of the present disclosure.

### DESCRIPTION OF REFERENCE SIGNS

100—light emitting device; 1—semiconductor light source; 11—first light emitting surface; 12—electrical connection surface; 13—second light emitting surface; 2—wavelength conversion member; 21—first abutting surface; 22—second abutting surface; 23—side wall; 24—first wavelength conversion film; 25—second wavelength conversion film; 26—third wavelength conversion film; 27—sealing body; 271—transparent layer; 272—reflective layer; 3—light extraction member; 4—light transmitting layer; 5—light inhibiting layer; 51—through hole; 52—rough surface; 6—expansion member; 61—expansion sheet; 611—front side; 612—back side; 613—step; 614—shielding; 62—insulating reflective coating; 7—adhesive member; 8—transparent sealing member; 200—display device; 210—substrate; 220—reflective cover; 230—diffusion sheet; 240—light-enhancing sheet.

### DETAILED DESCRIPTION OF THE EMBODIMENTS

In order to facilitate the understanding of the present disclosure, the present disclosure will be described more fully below with reference to relevant attached drawings. Preferred embodiments of the present disclosure are illustrated in the drawings. However, the present disclosure can be implemented in many different forms and is not limited to the embodiments described herein. On the contrary, providing these embodiments is to assist understanding the content disclosed by the present disclosure more fully and thoroughly.

It should be noted that when an element is called “fixed to” another element, it can be directly on another element or there can be a centered element. When an element is considered to be “connected to” another element, it can be directly connected to another element or there may be intermediate elements at the same time.

Unless otherwise defined, all technical and scientific terms used herein have the same meaning as commonly understood by one of ordinary skill in the art to which this application belongs. The terms used herein in the description of the present disclosure are for the purpose of describing specific embodiments only, and are not intended to limit the present disclosure.

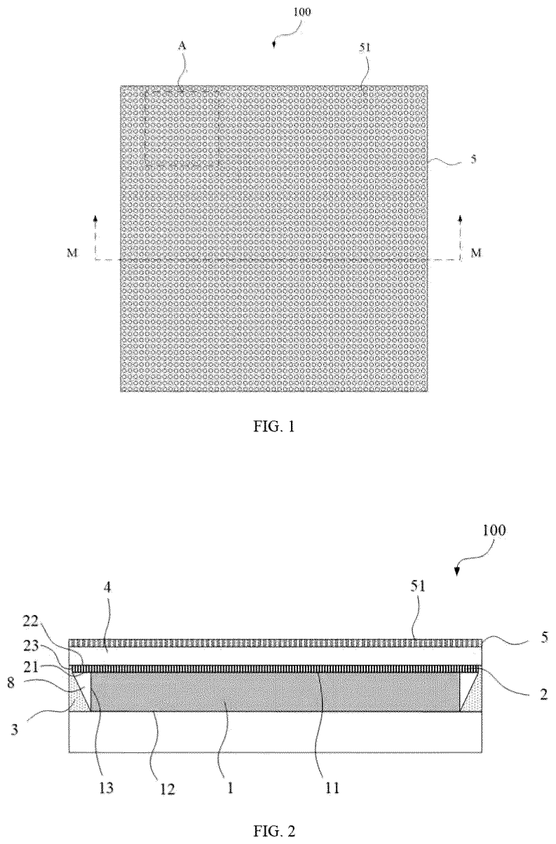

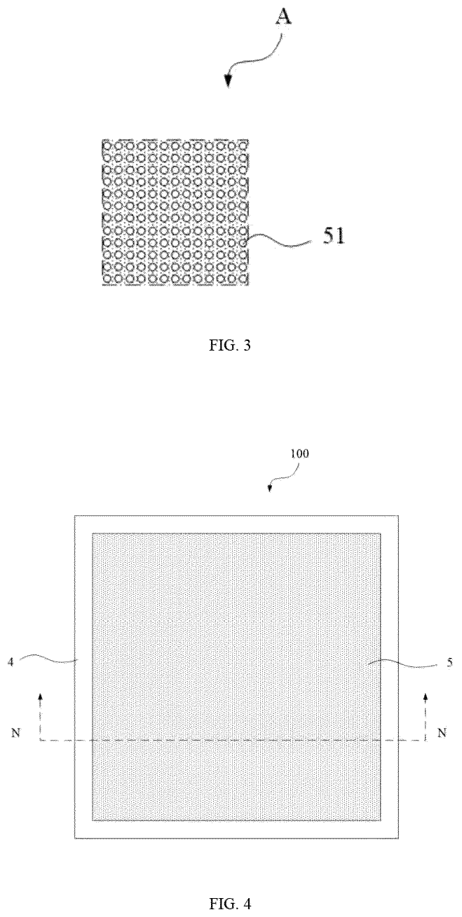

Referring to FIGS. 1 to 3, a light emitting device 100 according to a first embodiment of the present disclosure is provided. The light emitting device 100 includes a semiconductor light source 1, a wavelength conversion member 2, a light extraction member 3, a light transmitting layer 4, and a light inhibiting layer 5. It should be noted that the light emitting device 100 in the embodiment of the present disclosure generates white light based on the principle that the semiconductor light source 1 emitting blue light excites the phosphors emitting red light and green light in the wavelength conversion member 2 to generate white light. Certainly, other colors or other combinations that produce white light are also suitable for the structures of the embodiments of the present disclosure. In addition, the overall size of the light emitting device 100 of the present disclosure can be very small, and a light-emitting semiconductor can also be a conventional blue light chip. In this case, the overall size of the light emitting device 100 can be no more than 1.2 times that of the chip, which is a chip-level size.

The semiconductor light source 1 includes a first light emitting surface 11, an electrical connection surface 12, and a plurality of second light emitting surfaces 13. The semiconductor light source 1 is a cuboid, the first light emitting surface 11 is a top light emitting surface, and the second light emitting surface 13 is a side light emitting surface. The electrical connection surface 12 is provided with two electrical connection members (such as electrodes), the electrical connection surface 12 is opposite to the first light emitting surface 11. The plurality of second light emitting surfaces 13 are connected between the electrical connection surface 12 and the first light emitting surface 11. The semiconductor light source 1 in the embodiment of the present disclosure is a cuboid blue light chip with four first light emitting surfaces 11. Certainly, other forms or shapes of semiconductor light sources 1 are not limited to the embodiment of the present disclosure.

The wavelength conversion member 2 is stacked on the first light emitting surface 11 and includes a first abutting surface 21 and a second abutting surface 22 that are opposite to each other and a side wall 23 connected between the first abutting surface 21 and the second abutting surface 22. The wavelength conversion member 2 is configured to receive and convert a wavelength of light. The first abutting surface 21 is in contact with the first light emitting surface 11. In the embodiment of the present disclosure, the wavelength conversion member 2 is a phosphor film, which is formed by mixing phosphor powder or quantum dot phosphor powder with silica gel and then uniformly spraying the mixture onto a steel mesh. In other embodiments, the wavelength conversion member 2 is a fluorescent colloid, which is formed by directly mixing the phosphor powder with transparent silicone resin and then sealing the mixture in the colloid.

The light extraction member 3 surrounds the semiconductor light source 1 and the wavelength conversion member 2, and includes a surrounding wall that continuously surround the plurality of second light emitting surfaces 13. The surrounding wall extends along a periphery of the plurality of second light emitting surfaces 13 and is spaced apart from the second light emitting surfaces 13. At the same time, the surrounding wall further abuts against the side wall 23 of the wavelength conversion member 2 to seal the semiconductor light source 1. A top portion of the surrounding wall is coplanar with the second abutting surface 22 of the wavelength conversion member 2, so that the light emitted from the semiconductor light source 1 passes through the wavelength conversion member 2 and then is emitted from the second abutting surface 22. Optionally, the light extraction member 3 of the embodiment of the present disclosure is made of, including but is not limited to, a light reflective film with high reflectivity. The light reflective film is preferably white resin. The white resin is made of a light-transmitting resin filled with white pigment. The white pigment can include but not limited to titanium oxide, aluminum oxide, zinc oxide, barium carbonate, barium sulfate and glass fillers, etc. In addition, the surrounding wall may also be provided with a reflective surface opposite to the second light emitting surface 13. In the embodiment of the present disclosure, the reflective surface is an inclined plane forming an included angle of less than 90 degrees with the second light emitting surface 13. In other embodiments, the reflective surface may be an arc surface having a certain curvature.

A space between the second light emitting surface 13 and an inner wall of the light extraction member 3 is filled with a transparent sealing member 8. The light extraction member 3 collects the blue light emitted from the second light emitting surface at a top portion thereof, and the blue light from the second light emitting surface passes the wavelength conversion member 2 at the top to generate white light, just like the blue light emitted from the first light emitting surface 11, so as to ensure that as much white light as possible enters the light transmitting layer 4. The above arrangement of the semiconductor light source 1, the wavelength conversion member 2 and the light extraction member 3 can prevent the blue light of the semiconductor light source 1 from leaking while enhancing the brightness of the light.

The light transmitting layer 4 covers the top portions of the light extraction member 3 and the wavelength conversion member 2 away from the semiconductor light source 1, that is, the light transmitting layer 4 is stacked on the second abutting surface 22. A projection of a peripheral edge of the light transmitting layer 4 in a stacking direction coincides with a peripheral edge of the light extraction member 3, which facilitates the preparation of the light emitting device 100. The space between the semiconductor light source 1 and the light extraction member 3 is filled with the transparent sealing member 8. A transparent sealing body 27, the light extraction member 3, and the light transmitting layer 4 abut against and seal the wavelength conversion member 2 By providing the light transmitting layer 4 with an appropriate thickness, an overall thickness of the light emitting device 100 can be prevented from being too thick, and at the same time, it can be ensured that light is emitted from the light transmitting layer 4 as much as possible.

The light inhibiting layer 5 is stacked on a top surface of the light transmitting layer 4 away from the wavelength conversion member 2, and is configured to partially inhibit a light emergent brightness the top surface of the light transmitting layer 4. In the embodiment of the present disclosure, the light inhibiting layer 5 can be made of the same high-reflectivity light-reflective film as that of the light extraction member 3, and the specific material can be referred to the above description. The light inhibiting layer 5 in the following embodiments is made of a light reflective film as an example. In conventional packaging structures, light reflective films or distributed Bragg reflectors are generally used to fully cover a top portion of the chip or to fully cover the light emitting surface at the top portion to achieve top light inhibition. This will result in a large loss of brightness of the entire structure. Excessive light inhibition at the top portion will also form a dark area at the top portion and greatly reduce the brightness of the light. In the first embodiment of the present disclosure, an area of a projection of the light inhibiting layer 5 on the second abutting surface 22 along the stacking direction is less than an area of a projection of the light transmitting layer 4 on the second abutting surface 22 along the stacking direction. In the first embodiment, the top surface of the light transmitting layer 4 is covered with the light inhibiting layer 5. The projections of the peripheral edges of the light inhibiting layer 5, the light transmitting layer 4, and the second abutting surface 22 coincide in the stacking direction. Only a plurality of holes through the light inhibiting layer 5 are provided, i.e., a peripheral edge of the light inhibiting layer 5 is coplanar with the peripheral edge of the light transmitting layer 4, but the holes are provided on the light inhibiting layer 5, so that an area of the light inhibiting layer 5 is less than an area of the top surface of the light transmission layer 4. Optionally, the plurality of holes are evenly distributed on the light inhibiting layer 5. By controlling a proportion of a total area of the plurality of holes in the area of the light inhibiting layer 5, the inhibition of the light at the top portion is adjusted, and then the light from the top portion is controlled. Optionally, the holes are provided in the light inhibiting layer 5 by a laser beam. Equally spaced and dense holes can be formed in the light inhibiting layer 5, so as to uniformly inhibit the light emitted from the top of the light emitting device 100.

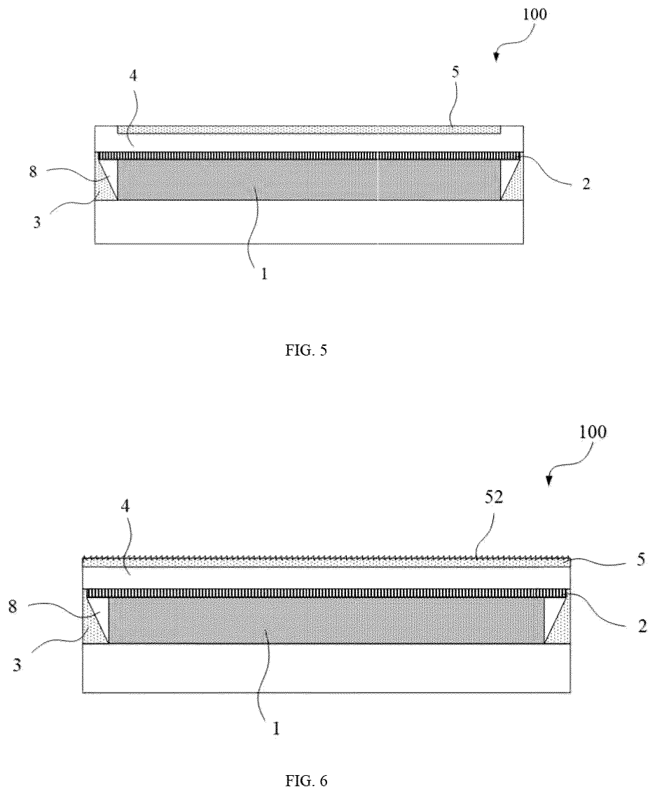

Referring to FIGS. 4 to 5, a light emitting device 100 according to a second embodiment of the present disclosure is provided. The light emitting device 100 includes a semiconductor light source 1, a wavelength conversion member 2, a light extraction member 3, a light transmitting layer 4, and a light inhibiting layer 5. The structure and positional relationship of the semiconductor light source 1, the wavelength conversion member 2, the light extraction member 3, and the light transmitting layer 4 are the same as those in the first embodiment. Please refer to the description in the first embodiment for details and will not be repeated herein. The difference between the second embodiment and the first embodiment lies in the structural arrangement of the light inhibiting layer 5. The light inhibiting layer 5 in the second embodiment is stacked on a top surface of the light transmitting layer 4 away from the wavelength conversion member 2 to partially inhibit the light emergent brightness a top surface of the light transmitting layer 4. In the second embodiment of the present disclosure, an area of a projection of the light inhibiting layer 5 on the second abutting surface 22 along a stacking direction is less than an area of a projection of the light transmitting layer 4 on the second abutting surface 22 along the stacking direction. In the second embodiment, the top surface of the light transmitting layer 4 is covered with the light inhibiting layer 5, projections of the peripheral edges of the light transmitting layer 4 and the second abutting surface 22 coincide in the stacking direction, and the projection of the peripheral edge of the light inhibiting layer 5 in the stacking direction falls within the light transmitting layer 4, i.e., the light inhibiting layer 5 only covers a center of the top surface of the light transmitting layer 4 and extends beyond the periphery of the top surface of the light transmitting layer 4. Optionally, in order to make the light inhibiting layer 5 and the light transmitting layer 4 more tightly bonded, the light transmitting layer 4 is provided with a groove (not shown), and the groove is recessed from the top surface of the light transmitting layer 4 toward the wavelength conversion layer. The light inhibiting layer 5 is accommodated in the groove. Optionally, cooperative concave and convex textures (not shown) can be provided on side surfaces where the light inhibiting layer 5 and the groove are connected, respectively, so as to secure the connection between the light inhibiting layer 5 and the groove.

Referring to FIG. 6, a light emitting device 100 according to a third embodiment of the present disclosure is provided. The light emitting device 100 includes a semiconductor light source 1, a wavelength conversion member 2, a light extraction member 3, a light transmitting layer 4, and a light inhibiting layer 5. The structure and positional relationship of the semiconductor light source 1, the wavelength conversion member 2, the light extraction member 3, and light transmitting layer 4 are the same as those in the first embodiment and the second embodiment. Please refer to the description in the first embodiment for details and will not be repeated herein. The difference between the third embodiment and the first embodiment and the second embodiment lies in the structural arrangement of the light inhibiting layer 5. Each of areas of the projections of the light inhibiting layer 5, the light inhibiting layer 5, and the light transmitting layer 4 on the second abutting surface 22 along a stacking direction is equal to an area of the second abutting surface 22, i.e., the light inhibiting layer 5 fully covers a side of the light transmitting layer 4 away from the wavelength conversion member 2, and a surface of the light inhibiting layer 5 away from the light transmitting layer 4 is a rough surface 52. Since the light inhibiting layer 5 fully covers a side of the top portion of the light transmitting layer 4 emitting the light, in order to allow the light inhibiting layer 5 to inhibit light emission while partially transmitting light, a surface of the light inhibiting layer 5 away from the light transmitting layer 4 is roughened to form a matte surface, so that part of the light can be transmitted through the top portion.

In the light emitting device 100 of the first to third embodiments of the present disclosure, the light emitted from the plurality of second light emitting surfaces 13 on a side of the semiconductor light source 1 is extracted through the light extraction member 3, and the light from the second light emitting surfaces 13 on the side is collected to the top portion and emitted to the wavelength conversion member 2 together with the light emitted from the first light emitting surface 11, and the white light is emitted from the second abutting surface 22 of the wavelength conversion member 2. After passing through the light transmission layer 4, the white light is emitted through the thickness direction of the light transmission layer 4 and the top portion provided with the light inhibiting layer 5. The white light at the top portion is partially inhibited by the light inhibiting layer 5 or partially transmitted through the plurality of uniform and dense holes. Alternatively, the light in the central area of the top portion of the light transmitting layer 4 is only inhibited by the light inhibiting layer 5, while the periphery of the top portion of the light transmitting layer 4 can transmit light normally. Alternatively, the light transmission is increased by roughening the side of the light inhibition layer 5 emitting light. The light emitting device 100 of the above embodiments can increase the overall light emission intensity and partially inhibit the light emitted from the top portion, thus avoiding the situation in the prior art that the top portion is directly completely inhibited which results in a dark area on the top portion and an excessive loss of overall brightness. In addition, when used in backlight devices, the light mixing distance can be small, the backlight device can be thinner and the overall brightness can be high.

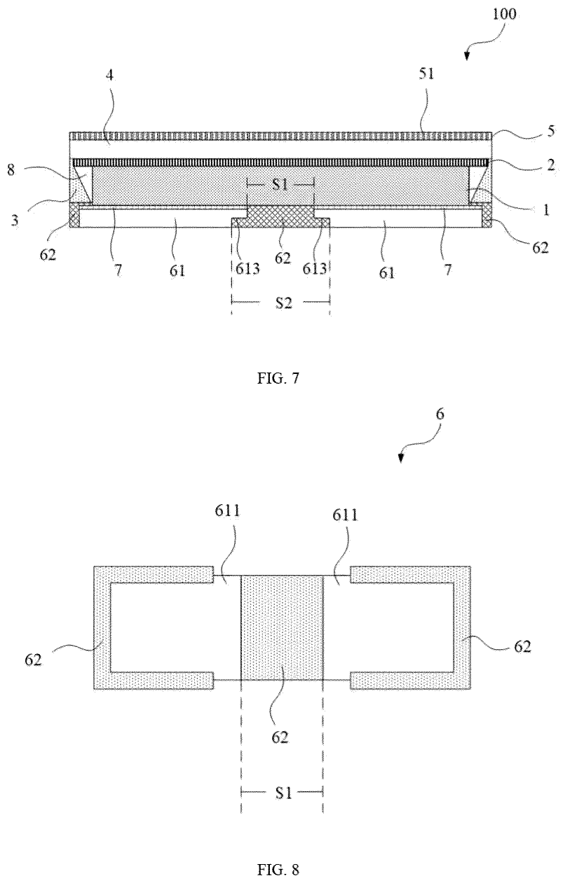

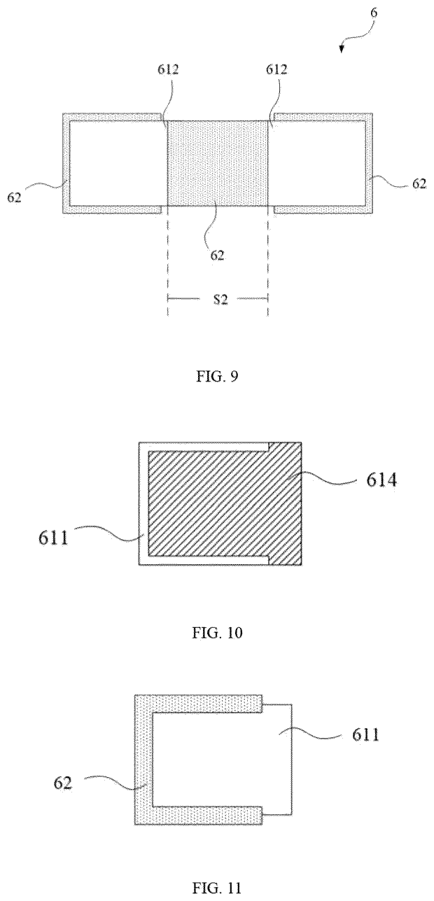

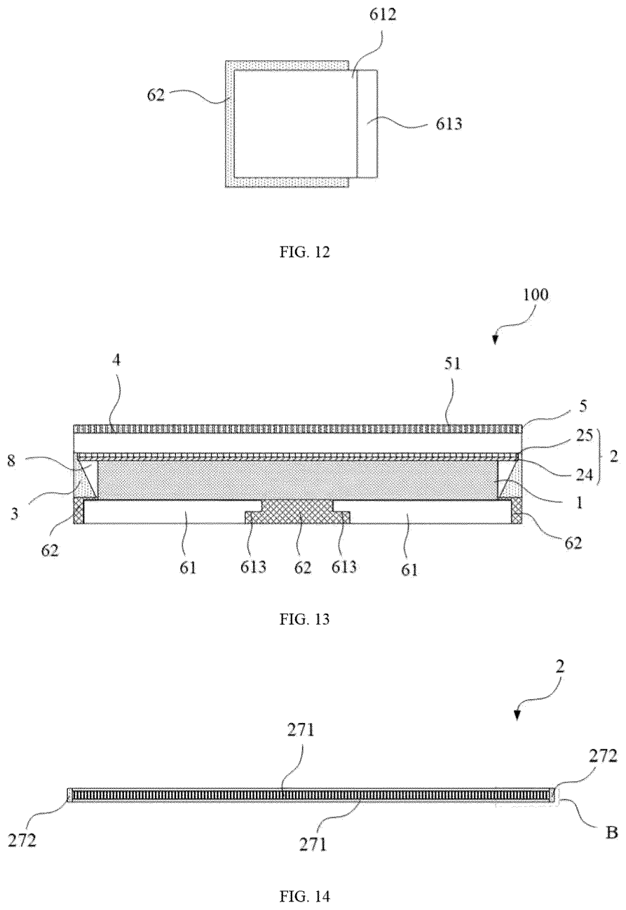

A fourth embodiment of the present disclosure provides a light emitting device 100. Referring to FIGS. 7 to 13, the light emitting device 100 includes a semiconductor light source 1, a wavelength conversion member 2, a light extraction member 3, a light transmitting layer 4, a light inhibiting layer 5, and an extension member 6. The structure and positional relationship of the semiconductor light source 1, the wavelength conversion member 2, the light extraction member 3, and the light transmitting layer 4 can be the same as those at least one of the first to third embodiments. Please refer to the descriptions in the first to third embodiments for details and will not be repeated herein. The fourth embodiment is based on the structure of the first to third embodiments and provides the expansion member 6 configured to expand an area of the electrical connection member of the semiconductor light source 1. In the practical application of the light emitting device 100 described above, an electrical connection structure (electrode) needs to be fixedly connected to the corresponding connection member (such as a pad on a carrier board). Since a size of the light emitting device 100 itself is small, its corresponding electrical connection structure is even smaller, and the difficulty of fixing is greater. Therefore, an expansion pad will be often prepared on the electrical connection structure of the light emitting device 100 to expand a welding area of the electrical connection structure. However, current expansion pads are all located on an insulated substrate, and the conductive expansion pads are provided on both the front and back sides of the substrate. A through hole is opened in a middle of the insulated substrate, the through hole is connected to the expansion pads on the front and back sides, and the through hole is filled with conductive material. If the overall thickness of the expansion pad is too thin, a metal layer filled in the through hole will easily break. The overall thickness is generally greater than 100 μm to 500 μm. A greater thickness will increase the overall thickness of the light emitting device 100. The expansion member 6 of the fourth embodiment of the present disclosure can be made thinner, and the thickness can reach 20 μm to 50 μm.

Optionally, the expansion member 6 includes two expansion sheets 61 spaced apart and an insulating reflective coating 62 covering the two expansion sheets 61 and having adhesiveness. The two expansion sheets 61 have the same structure and are symmetrically distributed. The two expansion sheets 61 is connected to the two electrical connection members of the semiconductor light source 1 in one-to-one correspondence. Each expansion sheet 61 has a front side 611 and a back side 612 that are opposite to each other. The front side 611 of each expansion sheet 61 is welded to the electrical connection member. The insulating reflective coating 62 covers the expansion sheet 61 in a form of completely exposing the back side 612 of the expansion sheet 61 and partially exposing the front side 611 of the expansion sheet 61, while the insulating reflective coating 62 further fills a gap between the two expansion sheets 61. The insulating reflective coating 62 located in the gap can not only connect two expansion sheets 61, but also can be configured to connect the expansion sheet 61 and the semiconductor light source 1. The insulating reflective coating 62 partially covering the front side 611 of the expansion sheet 61 can be configured to connect the semiconductor light source 1 and the expansion member 61. Since the preparation process requires multiple transfers on the adhesive film (such as UV film), the firmness of the connection between the expansion sheet 61 and the semiconductor light source 1 must be ensured, otherwise the expansion sheet 61 may fall off. Optionally, the expansion sheet 61 can be made of metal with good electrical conductivity such as copper or gold. Optionally, the two expansion sheets 61 have uniform thickness and the same volume. Optionally, the insulating reflective coating 62 may be white paint, and the white paint should also have adhesion, insulation and high reflectivity. The insulating reflective layer 272 can also reflect the light emitted from the semiconductor light source 1 and/or the light reflected by the light inhibiting layer 5.

Since a distance between the two electrical connection members is relatively small, the two electrical connection members are respectively connected to the two expansion sheets 61 correspondingly. During use, the distance between the expansion sheets 61 should be as large as possible to avoid a short circuit. On the basis of the fourth embodiment, steps 613 are provided on the back side 612 of the expansion sheet 61. The step 613 is formed by the back side 612 of the expansion sheet 61 being recessed toward the front side 611. The steps 613 of the two expansion sheets 61 are opposite to each other and are spaced, and the formed gap has an isosceles trapezoidal cross-section in the stacking direction. The arrangement of the above two expansion sheets 61 can make the distance S1 between the front sides 611 of the two expansion sheets 61 relatively small, while the distance S2 between the back sides 612 of the two expansion members 61 is greater than S1. The front side 611 meets the condition that the two electrical connection members are relatively close, and the back side 612 meets the condition that the two pads are far apart during mounting. At the same time, due to the gap between the two expansion sheets 61 is an isosceles trapezoid, then the insulating reflective coating 62 filled in the gap is also an isosceles trapezoid. The insulating reflective coating 62 in the form of an isosceles trapezoid in the gap improves the firmness of both the connection between the two expansion sheets 61 and the connection between the expansion sheet 61 and the semiconductor light source 1.

Although the insulating reflective coating 62 located in the gap can also connect the expansion sheet 61 and the semiconductor light source 1, it is not sufficient for only localized connection to maintain the overall firmness between the expansion sheet 61 and the semiconductor light source 1 during the preparation process. Optionally, since the insulating reflective coating 62 located on the front side 611 of the expansion sheet 61 needs to reserve a connection space for the electrical connection members, the insulating reflective coating 62 can only partially cover the front side 611 of the expansion sheet 61, and due to the distance between the two electrical connection members is relatively small and the two electrical connection members are connected to the two expansion sheets 61 respectively, then a connection point between the electrical connection member and the front side 611 of the expansion sheet 61 should be adjacent to the gap. Preferably, the insulating reflective coating 62 located on the front side 611 of the expansion sheet 61 is distributed along a periphery of the front side 611 of the expansion sheet 61 away from the gap and is in a U-shape. When preparing the U-shaped insulating reflective coating 62, a T-shaped shielding 614 is formed on the front side 611 of the expansion sheet 61 to form a U-shaped opening aligned with the gap. This arrangement allows the insulating reflective coating 62 to be evenly distributed on the front side 611 of the expansion sheet 61, which plays a good role in adhering the expansion sheet 61 to the semiconductor light source 1, while not affecting the connection between the electrical connection member and the front side 611 of the expansion sheet 61.

Due to the provision of the expansion member 6, the light emitting device 100 of the fourth embodiment will add a second reflow soldering process during subsequent mounting and use, so that the back side 612 of the expansion sheet 61 in the expansion member 6 is welded and fixed. However, since the front side 611 of the expansion sheet 61 is welded and fixed with the electrical connection member, if the welding (primary reflow soldering) between the expansion sheet 61 and the electrical connection member uses a conventional solidified connection with solder, during a secondary reflow soldering, in order not to affect the firmness of the primary reflow soldering, the secondary reflow soldering process uses low-temperature solder with volatile flux is used to solder the back side 612 of the expansion sheet 61, which affects the soldering strength. Therefore, in order to ensure the soldering strength of the secondary reflow soldering without melting the soldering of the primary reflow soldering, the front side 611 of the expansion sheet 61 and the electrical connection member are connected through an adhesive member 7. The adhesive member is a conductive member, which is different from conventional solder. The adhesive member 7 does not contain flux, and is pressurized with a pressure that does not cause plastic deformation as much as possible under the temperature conditions of the melting temperature or lower, so that the adhesive member 7 and the expansion sheet 61 or the base material of the electrical connection member are bonded to each other to allow the atoms created between the two surfaces to diffuse, thereby increasing the strength of the connection. More specifically, the adhesive member 7 includes gold alloy, silver alloy, palladium alloy, indium alloy, tin alloy, aluminum alloy, lead-palladium alloy, gold-gallium alloy, gold-tin alloy, tin-copper alloy, tin-silver alloy, gold-chromium alloy, gold-silicon alloy, copper-indium alloy mixture. Alternatively, the adhesive member 7 may be in a liquid form, a paste form, or a solid form (sheet form, block form, powder form, or wire form), and may be appropriately selected according to the composition and shape of a supporting member. In addition, the adhesive member 7 can be a single member or a combination of a plurality of members. Alternatively, the adhesive member 7 may be evaporated on the electrical connection member, or the adhesive member 7 may be electroplated on the expansion sheet 61.

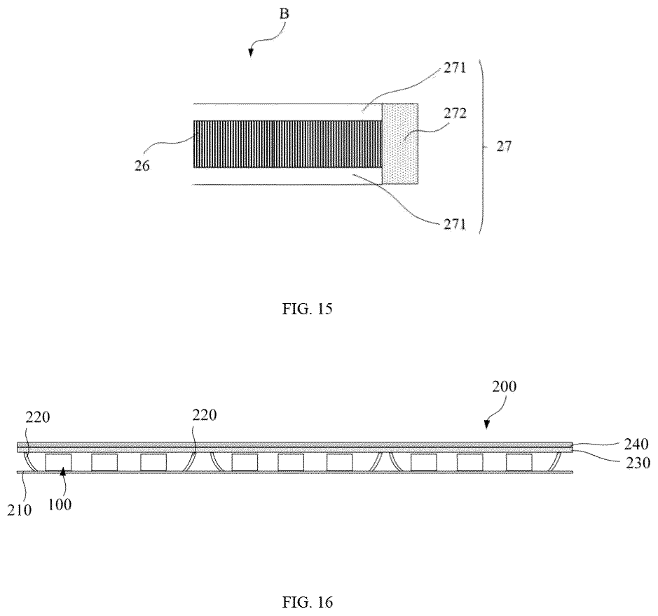

The embodiment of the present disclosure utilizes a blue light chip to excite red and green phosphors to emit white light, but usually red phosphors have poor stability under high temperature and high humidity annular conditions. Therefore, a fifth embodiment of the present disclosure provides a light emitting device 100. Based on the structures of the first, second, third, and fourth embodiments above, the light emitting device 100 of the fifth embodiment of the present disclosure may include a semiconductor light source 1, a wavelength conversion member 2, a light extraction member 3, a light transmitting layer 4, a light inhibiting layer 5 and/or an expansion member 6, and the wavelength conversion structure therein is modified. For other structural descriptions, please refer to the first, second, third, and fourth embodiments. Referring to FIGS. 14 to 16, the fifth embodiment 5 of the present disclosure provides two different types of wavelength conversion structures to improve the sealing performance of red phosphor. The structure of the first type of wavelength conversion member 2 includes a first wavelength conversion film 24 and a second wavelength conversion film 25 that are sequentially stacked along a side adjacent to the semiconductor light source 1. The first wavelength conversion film 24 excites light of a red wavelength band, and the second wavelength conversion film 25 excites light of a green wavelength band. The transparent sealing member 8 abuts against and seals the first wavelength conversion film 24. The first wavelength conversion film 24 is sealed within the second wavelength conversion film 25, the light extraction member 3 and the transparent sealing member 8, so as to improve the sealing performance of red phosphor. The structure of the second type of wavelength conversion member 2 includes a third wavelength conversion film 26 that simultaneously excites light of a red wavelength band and light of a green wavelength band, and a sealing body 27 surrounding the third wavelength conversion film 26. The sealing body 27 includes reflective layers 272 provided at both ends of the third wavelength conversion film 26 along a direction perpendicular to the stacking direction, and transparent layers 271 provided at both sides of the third wavelength conversion film 26 along the stacking direction. The transparent layers 271 and the reflective layers 272 wrap the third wavelength conversion film 26, and the transparent sealing member 8 abuts against and seals the transparent layer 271. The sealing performance of the red phosphor is improved through the peripheral sealing body 27.

A sixth embodiment of the present disclosure provides a display device 200. Referring to FIG. 16. The display device 200 includes a substrate 210, a plurality of light emitting devices 100, a reflective cover 220, a diffusion sheet 230, and a light-enhancing sheet 240. The light emitting device 100 includes the aforementioned structure of the light emitting device 100. A plurality of light emitting devices 100 are evenly arranged on the substrate 210, and the reflective cover 220 surrounds at least one light emitting device 100. For example, one reflective cover 220 can cover nine (3*3) light emitting devices 100 evenly arranged, or four (2*2) light emitting devices 100 evenly arranged, etc. The diffusion sheet 230 and the light-enhancing sheet 240 are sequentially stacked on the plurality of light emitting devices 100 along the side adjacent to the light emitting device 100. A projection of the light emitting device 100 in a direction parallel to the substrate 210 falls within the reflective cover 220, that is, a height of the light emitting device 100 relative to the substrate 210 is less than a height of the reflective cover 220 relative to the substrate 210. The diffusion sheet 230 can be directly covered on the reflective cover 220, and the diffusion sheet 230 is almost directly attached to the light emitting device 100. The light mixing distance approaches to zero to form the ultra-thin display device 200, and no bright spot or dark area appears, and the overall brightness is also intensified.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

1. A light emitting device, comprising:
a semiconductor light source comprising a first light emitting surface and an electrical connection surface opposite to each other, and a plurality of second light emitting surfaces connected between the first light emitting surface and the electrical connection surface, and two electrical connection members being provided on the electrical connection surface;
a wavelength conversion member stacked on the first light emitting surface, the wavelength conversion member comprising a first abutting surface that abuts against the first light emitting surface, a second abutting surface that is opposite to the first abutting surface, and a side wall connected between the first abutting surface and the second abutting surface, the wavelength conversion member being configured to receive and convert a wavelength of light;
a light extraction member surrounding the semiconductor light source and the wavelength conversion member, the light extraction member being spaced apart from the second light emitting surface and abuts against the side wall, the light extraction member being configured to extract light from the second light emitting surface;
a light transmitting layer stacked on the second abutting surface, and a projection of the light transmitting layer along a stacking direction completely covering the second abutting surface; and
a light inhibiting layer stacked on a top surface of the light transmitting layer away from the wavelength conversion member and configured to partially inhibit a light emergent brightness of the top surface of the light transmitting layer, and an area of a projection of the light inhibiting layer on the second abutting surface along the stacking direction being less than an area of a projection of the light transmitting layer on the second abutting surface along the stacking direction.

2. The light emitting device according to claim 1, wherein the light inhibiting layer is provided with a plurality of circular through holes, and the plurality of through holes are evenly distributed on the light inhibiting layer.

3. The light emitting device according to claim 2, wherein projections of peripheral edges of the light inhibiting layer, the light transmitting layer, and the second abutting surface coincide in the stacking direction.

4. The light emitting device according to claim 1, wherein projections of peripheral edges of the light transmitting layer and the second abutting surface coincide in the stacking direction, and a projection of the peripheral edge of the light inhibiting layer in the stacking direction falls within the second abutting surface.

5. The light emitting device according to claim 4, wherein the light transmitting layer is provided with a groove, and the groove is recessed from a surface of the light transmitting layer away from the wavelength conversion member toward the wavelength conversion member, the light inhibiting layer is accommodated in the groove, and the light inhibiting layer is coplanar with the light transmitting layer on a side away from the wavelength conversion member.

6. The light emitting device according to claim 1, further comprising an expansion member connected to the two electrical connection members of the semiconductor light source, wherein the expansion member comprises two expansion sheets spaced apart and each having a front side and a back side opposite to each other, and an insulating reflective coating covering the two expansion sheets and having adhesiveness, the front surfaces of the two expansion sheets are connected to the two electrical connection members in one-to-one correspondence, respectively, the insulating reflective coating covers the expansion sheet in a manner of exposing the back side of the expansion sheet and partially exposing the front side of the expansion sheet, the insulating reflective coating further fills a gap between the two expansion sheets, and the front side of the expansion sheet and the insulating reflective coating located in the gap are further connected to the semiconductor light source.

7. The light emitting device according to claim 6, wherein steps are provided on the back side of the expansion sheet, and the gap is formed between the steps of the two expansion sheets;
and/or, the insulating reflective coating located on the front surface of the expansion sheet is distributed along a periphery away from the gap and is in a U-shape.

8. The light emitting device according to claim 1, wherein a transparent sealing member is filled between the second light emitting surface and an inner wall of the light extraction member, the wavelength conversion member comprises a first wavelength conversion film and a second wavelength conversion film sequentially stacked along a side adjacent to the semiconductor light source, the first wavelength conversion film excites light of a red wavelength band, the second wavelength conversion film excites light of a green wavelength band, and the transparent sealing member abuts against and seals the first wavelength conversion film.

9. The light emitting device of claim 1, wherein sealing member is filled between the second light emitting surface and an inner wall of the light extraction member, the wavelength conversion member comprises a third wavelength conversion film that simultaneously excites light of a red wavelength band and light of a green wavelength band, reflective layers provided at both ends of the third wavelength conversion film along a direction perpendicular to the stacking direction, and transparent layers provided at both sides of the third wavelength conversion film along the stacking direction, the transparent layers and the reflective layers wrap the third wavelength conversion film, and the transparent sealing member abuts against and seals the transparent layer.

10. A display device, comprising:
a substrate,
a plurality of light emitting devices arranged on the substrate,
a reflective cover surrounding at least one of the light emitting devices, and
a diffusion sheet and a light-enhancing sheet that are stacked on the plurality of the light emitting devices, wherein the light emitting device comprises a structure of the light emitting device according to claim 1, a projection of the light emitting device in a direction parallel to the substrate falls within the reflective cover, the diffusion sheet abuts against the reflective cover, and the light-enhancing sheet is stacked on a side of the diffusion sheet away from the reflective cover.
